(19) United States
(12) Patent Application Publication
(10) Pub. No.: US 2010/0127723 A1
(43) Pub. Date: May 27, 2010

(54) PROBE POINT

(75) Inventors: Rand B. CARAWAN, Stafford, TX (US); Kendall S. WILLS, Sugar Land, TX (US); Reena A. CHANPURA, Sugar Land, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/275,529

(22) Filed: Nov. 21, 2008

(51) Int. Cl. G01R 1/06

(52) U.S. Cl. 324/757

(57) ABSTRACT

A system and method for reliably probing an internal node from the backside of an integrated circuit are disclosed herein. In accordance with at least some embodiments, an integrated circuit includes a device that outputs a signal, and a probe structure. The probe structure includes a transistor having each terminal of the transistor connected to all other terminals of the transistor and connected to the device output. The device output signal is applied to each terminal of the transistor.

### BACKGROUND

Integrated circuits, comprised of numerous circuit elements, are typically fabricated in layers on the surface of a semiconductor wafer. Many fabrication processes are repeated numerous times, constructing layer after layer until fabrication is complete. Metal layers (which typically increase in number as device complexity increases) include patterns of conductive material that are insulated from one another vertically by alternating layers of insulating material. Vertical, conductive tunnels called “vias” typically pass through insulating layers to form conductive pathways between adjacent conductive patterns.

Periodically, an electrical malfunction or design flaw causes an integrated circuit to malfunction during electrical testing. When this occurs, failure analysis is performed to determine the cause of the malfunction, and thereafter to take corrective action. Integrated circuit failure analysis often involves the use of several different types of equipment, or tools. One such failure analysis tool is the focused ion beam (“FIB”) apparatus, which can facilitate device modification.

Implementing a design change can be an expensive process. Typically, among other tasks, a circuit designer may have to produce new schematics, a vendor may need to supply new masks or other fabrication supplies, and wafer fab personnel may need to implement new process flows on various equipment sets. Rather than commencing a lengthy and costly redesign process only to have the new design fail in operation, it is often preferable to modify and test a physical sample of the integrated circuit using FIB technology prior to formalizing the modified design.

The FIB is a tool including one or more ion columns for generating ion beams. In general, the FIB is used for performing integrated circuit repair, editing, cross-sectioning, modifications to aid microprobing of the integrated circuit, and other common failure analysis applications.

A FIB system generates an ion beam from a liquid metal ion source-typically gallium. Positively charged gallium ions (“Ga^{+”}) are drawn off a field-emitter point source and accelerated by the application of a large potential, generally in the 25-50 kilovolt (kV) range, though in some systems the potential can be as low as 5 kV. With the aid of electrostatic lenses, the emission is focused into a beam typically having a sub-micron diameter. The ion beam can be used to mill through a sample integrated circuit, as may be required in failure analysis. The sample is usually positioned inside a vacuum chamber.

While the ion beam itself typically has a sputtering effect on the sample materials, there is often a need to add gases to assist in chemically removing material, thereby enhancing material removal process. Gas-assisted etching is a common feature in modern FIBs. An optional gas injection column delivers a localized gas to the area to be milled. This deposition gas can interact with the primary ion beam to provide selective gas-assisted chemical etching. Alternatively, the primary ion beam can be used to decompose a gas to provide selective deposition of conductive or insulating materials on the sample.

Electron beam (“E-beam”) probing systems are another valuable integrated circuit debugging tool. Using the principle of voltage contrast in scanning electron microscopes (“SEM”), E-beam probing allows reproduction of signals on internal nodes of the integrated circuit. These systems are essentially modified scanning electron microscopes, and consist of an electron beam, a means for directing the electron beam to a point on the integrated circuit under test, and a means for measuring the energy distribution of electrons leaving the point on the integrated circuit bombarded by the electron beam (i.e., secondary electrons). To probe an integrated circuit using E-beam, the electron beam is directed at a conductor, and the energy distribution of secondary electrons produced as a result of the electron bombardment is analyzed to determine the voltage on the conductor. The result of an E-beam measurement is relative, rather a true reading of the voltage at the measurement point of the circuit under test. To determine the exact voltage at any point of a circuit under test, physical contact with the circuit is required.

E-beam probing systems have traditionally been used on the front side of an integrated circuit. Gaining access to an internal node for E-beam probing from the backside of an integrated circuit generally involves thinning or removing the substrate below a node by chemical etching, FIB milling, or other appropriate means.

Another failure analysis tool, the laser voltage probe (“LVP”), uses an infra-red laser to illuminate a selected device in the integrated circuit. The LVP can be used from the backside of the integrated circuit because the integrated circuit's silicon substrate is at least partially transparent to the infra-red light. Parts of active elements within the IC reflect the light beam. Reflection of light in the IC occurs at interfaces between materials having different properties. The presence of a voltage drop across an interface, such as an interface between an N doped region and a P doped region of a semiconductor can also modify the reflectivity of the interface. Absorption of infra-red laser light illuminating a P-N junction increases at the junction based on the Franz-Keldysh effect in accordance with the junction reverse voltage, thus reducing the intensity of the reflected light. A time varying voltage across such an interface produces a time varying modulation of the reflectivity from the interface that can be measured and used to obtain information about the time varying voltage. Drains and sources of field effect transistors, diode junctions, etc, provide such P-N junctions. A detector in the LVP senses the changes in voltage across the interface through the modulated light reflections. LVP processing circuitry uses the detected reflections to create a representation of a signal at the selected device. The representation of the signal reflects only the state of the device under test as being higher in voltage drop or lower in voltage drop across the junction. The representation does not provide an accurate depiction of the device voltage.

Dual laser voltage probing employs a pair of lasers to mitigate problems arising when effects other than the one being probed result in unwanted light modulations. For example, temperature changes and movement of the integrated circuit being probed or the laser can produce noise in the reflected light. Dual laser voltage probing uses a first laser to measure integrated circuit vibrations. The first laser measurements are then used to normalize a second laser's measurements of electrical activity at the selected device.

As integrated circuit geometries are reduced, the internal nodes of the integrated circuit become more and more difficult to probe. Smaller structures provide less area for making FIB connections, and reflect less light making LVP less effective. Such probing difficulties can make failure analysis problematic and ultimately increase the cost of producing an integrated circuit. Circuit structures that optimize the effectiveness of failure analysis tools are desirable.

### SUMMARY

Various apparatus and methods for providing reliable probing of an internal node of an integrated circuit are disclosed herein. In accordance with at least some embodiments, an integrated circuit includes a device that outputs a signal, and a probe structure. The probe structure includes a transistor having each terminal of the transistor connected to all other terminals of the transistor and connected to the device output. The device output signal is applied to each terminal of the transistor.

In accordance with at least some other embodiments, a method includes probing an internal node of an integrated circuit through a transistor having all of its terminals shorted to a signal of interest.

In accordance with yet other embodiments, a semiconductor device includes a probe point accessible from a backside of a die, the probe point comprising an expendable transistor having a gate, source, and drain shorted together.

### BRIEF DESCRIPTION OF THE DRAWINGS

For a detailed description of exemplary embodiments of the invention, reference will now be made to the accompanying drawings in which:

FIG. 1 shows a cross-section view of a portion of an exemplary integrated circuit including a probe point in accordance with various embodiments;

FIG. 2 shows a top view of a portion of an exemplary integrated circuit including a probe point in accordance with various embodiments;

FIG. 3 shows a cross-section view of a portion of an exemplary integrated circuit including a probe point used for laser voltage probing in accordance with various embodiments;

FIG. 4 shows a top view of a portion an exemplary integrated circuit including a probe point used for laser voltage probing in accordance with various embodiments;

FIG. 5 shows a cross-section view of a portion of an exemplary integrated circuit including a probe point used for circuit editing with a focused ion beam (“FIB”) in accordance with various embodiments;

FIG. 6 shows a top view of a portion of an exemplary integrated circuit including a probe point used for circuit editing with a FIB in accordance with various embodiments;

FIG. 7 shows a cross-section of a portion of an exemplary integrated circuit and assorted probing problems mitigated by various embodiments; and

FIG. 8 shows a flow diagram for a method for probing an internal node of an integrated circuit including a probe point in accordance with various embodiments.

### NOTATION AND NOMENCLATURE

Certain terms are used throughout the following description and claims to refer to particular system components. As one skilled in the art will appreciate, companies may refer to a component by different names. This document does not intend to distinguish between components that differ in name but not in function. In the following discussion and in the claims, the terms “including” and “comprising” are used in an open-ended fashion, and thus should be interpreted to mean “including, but not limited to . . . . ” The term “integrated circuit” refers to a set of electronic components and their interconnections (internal electrical circuit elements, collectively) that are patterned on the surface of a microchip. The term “semiconductor device” refers generically to an integrated circuit (“IC”) or portion thereof, which may be integral to a semiconductor wafer, singulated from a wafer, or packaged for use on a circuit board. Also, the term “couple” or “couples” is intended to mean either an indirect or direct electrical connection. Thus, if a first device couples to a second device, that connection may be through a direct electrical connection, or through an indirect electrical connection via other devices and connections. The phrase “directly coupled” is intended to mean a direct physical and/or electrical connection with no electrical devices connected interstitially between the two coupled devices. To the extent that any term is not specially defined in this specification, the intent is that the term is to be given its plain and ordinary meaning.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Disclosed herein are apparatus and methods for creating a probe point accessible from the backside of an integrated circuit. The term “probe,” as used herein, refers to any of a variety of methods for accessing an internal node of an integrated circuit. The physical feature size of modern integrated circuits has been reduced to the point where internal nodes are so small that probing the nodes using available tooling is difficult. Consequently, dedicated probe points are inserted into the integrated circuit by design. Embodiments of the present disclosure include a novel probe point that allows access to an internal node by various means, including focused ion beam (“FIB”) milled vias, electron beams (“E-beam”) and laser voltage probes (“LVP”).

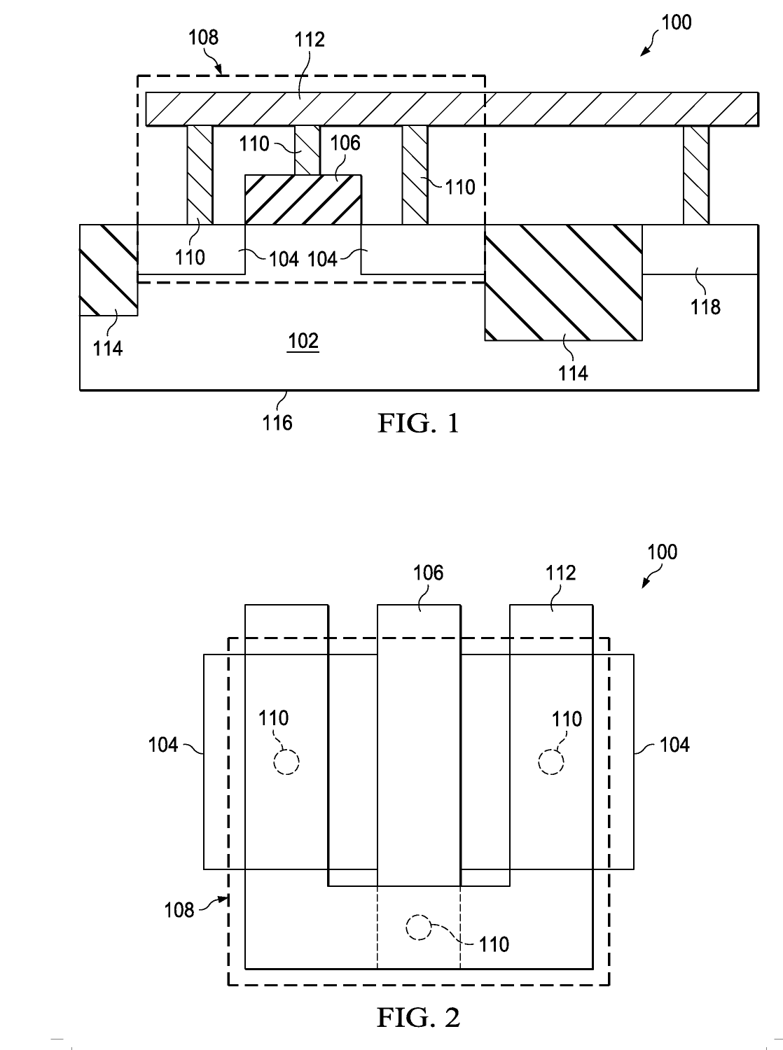

FIG. 1 shows a cross-sectional view of a portion of an exemplary integrated circuit 100 that includes a probe point 108 in accordance with various embodiments. The integrated circuit 100 includes a substrate 102 (e.g., a silicon base layer) upon which various semiconductor devices are constructed. Surface 116 is the backside of the integrated circuit 100, wherein no semiconductor devices are constructed. As a matter of convenience, only a portion of the integrated circuit 100 including the structures of the probe point 108 is illustrated, while in practice the integrated circuit 100 can include a plurality of semiconductor devices (e.g., transistors, diodes, resistors, etc.) that are not shown in FIG. 1. Embodiments of the present disclosure encompass all such integrated circuits.

In embodiments of the present disclosure, the probe point 108 is preferably constructed as a transistor. In FIG. 1, the probe point 108 comprises a transistor formed from active regions 104, which can be, for example, the source and drain of a field effect transistor (“FET”), and a gate structure 106. The gate structure 106 may be, for example, a polysilicon (“poly”) or a metal gate. Embodiments of the probe point 108 can comprise, for example, an N-channel FET or a P-channel FET.

Each of the gate, source and drain form a terminal of the probe point 108 transistor. A contact 110 is preferably formed above each terminal (i.e., away from the backside of the die) and connects to each terminal to conduct signals to/from the transistor. In general, a contact provides a vertical conductive path that connects a device (e.g., the source, drain, or gate of MOSFET) to a conductive network (e.g., a metal layer). The contacts 110 can be composed of tungsten or any other suitable material, for example, copper, aluminum, or an alloy. Embodiments further include a metal layer 112 that connects each contact 110 to other devices, for example, active region 118, on the integrated circuit 100. The metal layer 112 can comprise, for example, copper, aluminum, or any other appropriate conductor.

In embodiments of the present disclosure, the terminals of the probe point 108 transistor are electrically connected to one another (i.e., shorted together). Preferably, the terminals are shorted by a conductor formed from metal layer 112 that interconnects the contacts 110. The metal layer 112 also preferably connects a signal of interest (i.e., a signal that can be probed using the probe point 108) originating from another device (e.g., active region 118) on the integrated circuit 100 to each contact 110 of the probe point 108. For example, the active region 118 can be the source or drain of a transistor of interest on the integrated circuit 100, and can be connected to contacts 110 by metal layer 112. Thus, the signal of interest preferably is applied to each of the terminals of the probe point 108 transistor.

In at least some embodiments, the probe point 108 is isolated from other devices on the integrated circuit 100 by isolation regions 114, that can be, for example, shallow trench isolators (“STI”).

FIG. 2 shows a top view of a portion of an exemplary integrated circuit 100 including a probe point 108 in accordance with various embodiments. As described above, the active regions 104, and the gate 106 of the probe point 108 transistor are connected by contacts 110 to the metal layer 112. The metal layer 1 12, preferably shorts the contacts 110, and consequently shorts the three terminals of the transistor. The metal layer 112 also preferably connects a signal of interest to the probe point 108.

By shorting the terminals of the probe point 108 transistor, the transistor is not used in a conventional manner. However, the structure of the probe point 108 enhances the Franz-Keldysh effect by providing more voltage change at the edges of the active regions 104 and more voltage change in the depletion region under the gate 106. Consequently, the reflectivity of the probe point 108 is optimized, making probe point 108 better suited to laser voltage probing than a conventionally configured transistor of the same size.

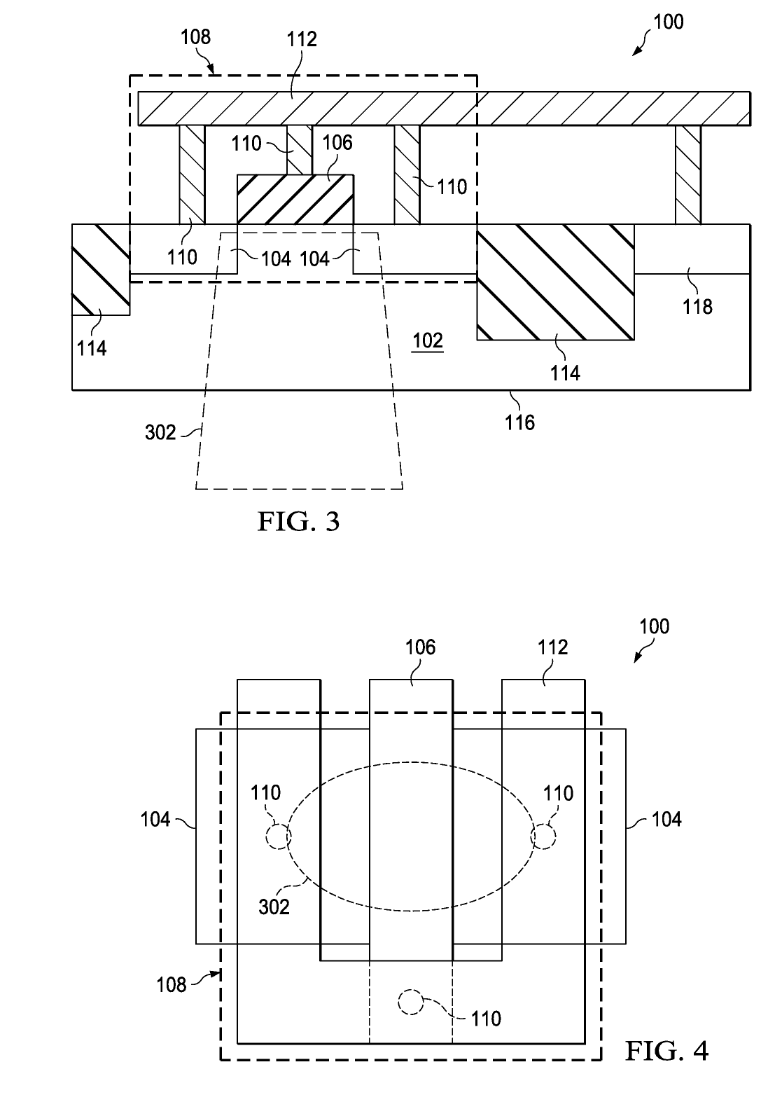

FIG. 3 shows a cross-section view of a portion of an exemplary integrated circuit 100 including a probe point 108 used for laser voltage probing in accordance with various embodiments. The laser beam 302 illuminates the probe point 108 through the substrate 102. The area of probe point 108 operable to reflect the laser in accordance with a signal of interest applied the active regions 104 and the gate 106 is optimized by applying the signal to all three terminals of the probe point 108 transistor. Thus, as shown in FIG. 3, the depletion region under the gate 106 and the edges of the active regions 104 are operable to reflect the laser 302. Consequently, embodiments of the present disclosure are better adapted for use with an LVP than circuits employing conventionally configured transistors of similar size.

FIG. 4 shows a top view of a portion of an exemplary integrated circuit 100 including a probe point 108 used for laser voltage probing in accordance with various embodiments. As explained above, embodiments of the present disclosure optimize the laser beam probe area. The probe area preferably comprises the depletion region under the gate structure 106, and the edges of the active regions 104. Thus, embodiments of the present disclosure allow implementation of smaller probe points 108 that reflect more light than conventionally configured transistors.

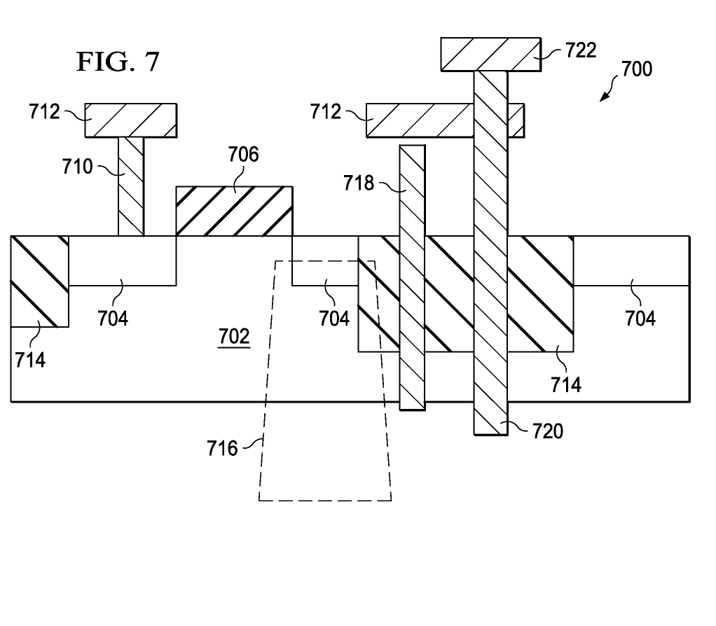

Referring now to FIG. 7, which shows a cross-section of a portion of an exemplary integrated circuit 700 and assorted probing problems avoided by various embodiments of the present disclosure. The integrated circuit 700 includes a substrate 702 on which a transistor comprising active regions 704 (e.g., source and drain), and gate structure 706 are constructed. These features are connected by contacts 710 to a metal layer 712. The transistor is isolated from other devices by isolation regions 714. In FIG. 7, the transistor is configured to operate in a conventional manner (i.e., the three terminals of the transistor are not shorted as in embodiments of the present disclosure). Therefore, the area operable to reflect laser light 716 from an LVP is restricted to the edges of the active region 704 (i.e., the P-N junction) as shown. Thus, the reflectivity and the effectiveness for use with LVP are reduced in comparison to integrated circuit embodiments including probe point 108.

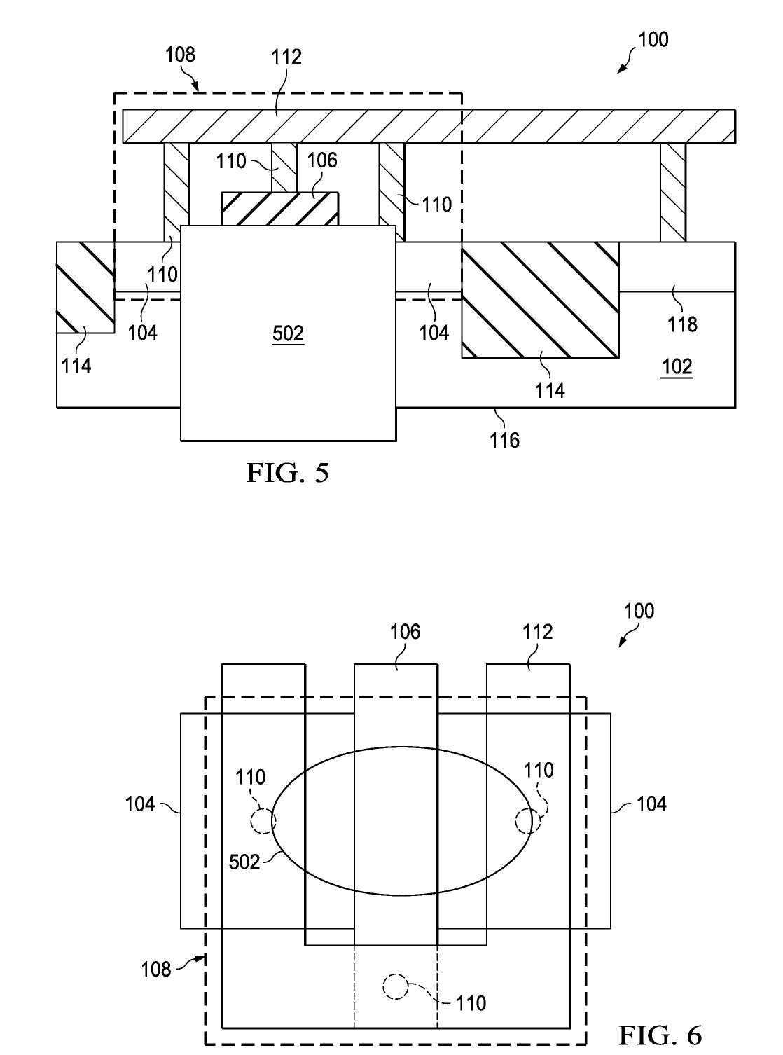

FIG. 5 shows a cross-section view of a portion of an exemplary integrated circuit 100 including a probe point 108 used for circuit editing with a FIB in accordance with various embodiments. As explained above, the FIB removes material to create a hole and deposits material to create insulators or conductors. In FIG. 5, a FIB is used to mill a hole and deposit a conductor, for example, tungsten, in the hole to create via 502. Note that an insulator is preferably deposited in the hole prior to deposition of the conductor to isolate the conductor from the substrate 102.

Establishing a via endpoint (e.g., suspending FIB milling) at a desired point in an integrated circuit is problematic, and the problem is exacerbated with shrinking feature sizes. As shown in FIG. 7, in an integrated circuit 700 lacking the probe structure 108, a via 718 can be milled through STI 714 in an attempt to connect to metal layer 1 712. Detecting the metal layer can be difficult, and if milling is suspended before the metal layer 712 is reached, the resulting via 718 does not make an electrical connection to the metal layer 712. Via 720 illustrates one consequence of over milling when the metal layers 712, 722 are tightly spaced. Via 720 is intended to connect to metal layer 1 712, but overshoots metal layer 1 712 and creates a short circuit between metal layer 1 712 and metal layer 2 722. Various other problems, such as shorting two conductors formed from the same metal layer as a result of misplacing a via are also common.

Embodiments of the present disclosure overcome the difficulties mentioned above and various other problems encountered in FIB circuit editing. In FIG. 5, the via 502 is milled through the expendable transistor of probe point 108 to the contacts 110. The contacts 110 are each connected to the signal of interest, and provide substantial metal for connection to the via 502. A viable connection to the via 502 can be attained over the entire length of the contacts 110, allowing for more over milling that can be tolerated in embodiments lacking the probe point 108. Moreover, because the probe point 108 is expendable, no concerns regarding the operation of the transistor after milling arise as in cases where a via is milled through a conventionally configured transistor.

FIG. 6 shows a top view of a portion of an exemplary integrated circuit including a probe point 108 used for circuit editing with a FIB in accordance with various embodiments. The metal layer 112 connects a signal of interest to probe point 108 transistor active regions 104 and to the gate structure 106 through the contacts 110. The via 502 is milled through the substrate 102 and the transistor active regions 104 to make an electrical connection with the contacts 110. The via 502 allows for circuit editing and probing of the signal of interest, for example, using a needle probe at a via 502 point on the outside surface 116 of the substrate 102.

Each of the probe point 108 structures described above, including the active regions 104, gate structure 106, contacts 110, and metal layer 112 can be created using conventional integrated circuit fabrication methods and materials.

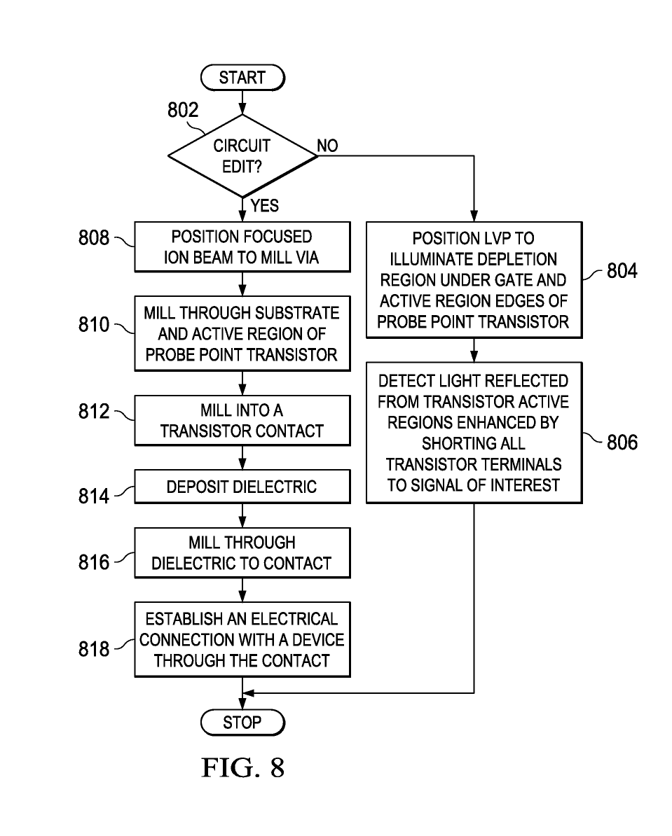

FIG. 8 shows a flow diagram for a method for probing an internal node of an integrated circuit 100 including a probe point 108 in accordance with various embodiments. Though depicted sequentially as a matter of convenience, at least some of the actions shown can be performed in a different order and/or performed in parallel. Additionally, some embodiments may perform only some of the actions shown.

In block 802, a determination is made as to whether to perform a circuit edit or an LVP. If an LVP is to be performed, then in block 804, the laser is positioned over the backside of the die so that the laser illuminates the depletion region under the gate structure 106 and the edges of the active regions 104 of the probe point 108 transistor. The three terminals of the probe point 108 transistor are electrically connected (i.e., shorted) to a signal of interest (i.e., the signal to be probed). This transistor configuration enhances the Franz-Keldysh effect, causing reflection of more laser light due to the voltage applied to the transistor terminals than is reflected by a conventionally configured transistor or diode of similar size. In block 806, the light reflected from the probe point 108 transistor active regions 104 and depletion region under gate structure 106 is detected and processed to generate a representation of the signal of interest.

If a circuit edit is to be performed (i.e., a connection to an internal node of the integrated circuit 100 is to be made), then in block 808, the FIB is positioned at the appropriate location over the backside 116 of the die to mill a hole to the probe point 108. The ion beam mills through the substrate 102 and the active regions 104 of the probe point 108 transistor in block 810. In block 812, the FIB mills into the contacts 110. The hole milled through the probe point 108 transistor active regions 104 does not detrimentally effect the operation of the integrated circuit 100 because the probe point 108 transistor is expendable.

In at least some embodiments, in block 814, a dielectric, for example silicon dioxide, is deposited in the hole to isolate the via 502 conductor from the substrate 102. In block 816, the FIB mills through the deposited dielectric to the contacts 110. In block 818, the hole to the contacts 110 is filled with a conductor to form a via 502 between a device providing the signal of interest (e.g., device active region 118) and the backside 116 of the integrated circuit 100. Thus, a signal of interest can be physically probed through an electrical connection between an internal conductor and the backside 116 of the integrated circuit 100. Note, however, that after performing the FIB operations explained above, the probe point 108 is no longer useable for LVP or other optical probing techniques due to damage to the probe point 108 junctions and the backside 116 of the integrated circuit 100.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. An integrated circuit, comprising:
a device that outputs a signal; and
a probe structure comprising a transistor,
wherein each terminal of the transistor is connected to all other terminals of the transistor and connected to the device output, and the device output signal is applied to each terminal of the transistor.

2. The integrated circuit of claim 1, wherein the probe structure further comprises contacts that connect each terminal of the transistor to a first metal layer that connects the terminals.

3. The integrated circuit of claim 2, wherein the first metal layer connects the contacts to the device output.

4. The integrated circuit of claim 2, further comprising a focused ion beam milled via that is connects to at least one of the contacts.

5. The integrated circuit of claim 1, wherein the probe structure is operable for physical, optical, and electron beam probing of the integrated circuit.

6. The integrated circuit of claim 1, wherein the transistor's reflectivity of laser light in accordance with a signal applied to the transistor is enhanced by connecting all the terminals of the transistor.

7. The integrated circuit of claim 1, wherein the transistor is a field effect transistor having a gate, source, and drain electrically connected to one another.

8. The integrated circuit of claim 1, wherein the transistor is expendable.

9. A method, comprising:
probing an internal node of an integrated circuit through a transistor having all of its terminals shorted to a signal of interest.

10. The method of claim 9, further comprising:
milling a via through the substrate of an integrated circuit; and
connecting the via to a contact of the transistor, wherein all contacts connected to the transistor are shorted together.

11. The method of claim 10, further comprising milling the via through the transistor without affecting operation of the integrated circuit.

12. The method of claim 10, further comprising over milling the via and maintaining isolation between a first metal layer connected to the contact and a second metal layer.

13. The method of claim 10, further comprising shorting together any of a source, drain, and gate region of the transistor through the via without affecting operation of the integrated circuit.

14. The method of claim 9, further comprising:
illuminating at least a portion of the transistor with a laser beam;
reflecting the laser from edges of the transistor active regions enhanced by connecting all transistor terminals to the signal of interest.

15. A semiconductor device, comprising:
a probe point accessible from a backside of a die, the probe point comprising an expendable transistor having a gate, source, and drain shorted together.

16. The semiconductor device of claim 15, further comprising contacts connected to each of the gate, source, and drain, wherein each of the contacts connects to a metal layer that electrically connects the gate, source, and drain.

17. The semiconductor device of claim 16, further comprising a focused ion beam milled via directly coupled to at least one of the contacts from the backside of the die.

18. The semiconductor device of claim 15, wherein each of the gate, source and drain are connected to a signal of interest.

19. The semiconductor device of claim 15, wherein the transistor's laser reflectivity is enhanced by shorting the gate, source, and drain.
